(19) United States
(12) Patent Application Publication
(10) Pub. No.: US 2009/0250109 A1
(43) Pub. Date: Oct. 8, 2009

(54) ACRYLIC PRESSURE SENSITIVE ADHESIVE COMPOSITION, DOUBLE COATED ADHESIVE SHEET, AND PHOTOVOLTAIC DEVICE

(75) Inventor: Naoki HASEGAWA, Tokyo (JP)

Correspondence Address: HESLIN ROTHENBERG FARLEY & MESITI PC, 5 COLUMBIA CIRCLE, ALBANY, NY, 12203, US

(73) Assignee: TOYO INK MANUFACTURING CO., LTD, Tokyo (JP)

(21) Appl. No.: 12/413,573

(22) Filed: Mar. 29, 2009

Related U.S. Application Data
(60) Provisional application No. 61/040,928, filed on Mar. 31, 2008.

(51) Int. Cl. H01L 31/04; B32B 27/08; B32B 7/02; C08K 5/1515; H01L 31/02

(52) U.S. Cl. 136/256; 428/473.5; 428/214; 524/114

(57) ABSTRACT

An acrylic pressure sensitive adhesive composition comprising (A) an acrylic polymer having a carboxyl group and (B) a tetrafunctional epoxy compound, without a substantial amount of a tackifying resin, wherein the acrylic polymer (A) has been prepared by copolymerizing (a) 50% to 80% by weight of butyl acrylate, (b) 5% to 40% by weight of ethyl acrylate, and (c) 7% to 22% by weight of at least one carboxyl group-containing compound selected from the group consisting of acrylic acid, methacrylic acid, itaconic acid, crotonic acid, monobutyl maleate and β-carboxyethyl acrylate; and which has a weight-average molecular weight (Mw) of about 600000 to about 800000 and a glass transition temperature of −35° C. to −10° C., is disclosed. Further, a double-coated adhesive sheet comprising the acrylic pressure sensitive adhesive composition, and a photovoltaic device fabricated, using the double-coated adhesive sheet, is disclosed.

This application claims the benefit of U.S. Provisional Patent Application Ser. No. 61/040,928, filed Mar. 31, 2008, which is hereby incorporated by reference in its entirety.

### BACKGROUND OF THE INVENTION

1. Field of the Invention

The present invention relates to an acrylic pressure sensitive adhesive composition, a double-coated adhesive sheet containing the acrylic pressure sensitive adhesive composition, and a photovoltaic device fabricated from the double-coated adhesive sheet. The photovoltaic device according to the present invention can effectively be used particularly in a solar cell.

2. Description of the Related Art

A solar cell in which photovoltaic elements are used has attracted attention as an alternative energy source which can solve problems in the conventional methods of generating power, such as thermal power generation, or hydroelectric power generation. Especially, an amorphous silicon solar cell enables to fabricate a solar cell at a lower cost as well as with a larger area, in comparison with a crystal solar cell, and therefore, various researches thereon are conducted. One of important technical problems in practical realization of the amorphous silicon solar cell is an improvement in the photoelectric conversion efficiency. To solve this technical problem, various investigations are intensively carried out. A known element constituting an amorphous silicon solar cell is, for example, a photovoltaic element prepared by laminating a lower electrode, a semiconductor layer, and a light receiving transparent electrode on an electrically conductive substrate, in the above order. The light receiving transparent electrode is formed from, for example, a transparent electroconductive oxide.

Further, collecting electrodes of a thin metal for collecting an electric current generated at each photovoltaic element are deposited on the surface of the light receiving transparent electrode. The collecting electrode is placed on a light receiving surface of a solar cell, and thus, the area of the collecting electrode becomes a so-called shadow loss to reduce an effective area contributing to an electric power generation of a solar cell. Therefore, the collecting electrode is arranged in the form of a comparatively thin comb. Further, the collecting electrode usually is thin and long, and thus, the material therefor and the section shape thereof are required so that an electric resistance thereof is lowered. In U.S. Pat. No. 5,084,107, the use of a metallic wire is proposed as a collecting electrode. U.S. Pat. No. 4,348,546 discloses methods for forming a collecting electrode. U.S. Pat. No. 4,260,429 and No. 4,283,591 disclose the technique of forming an electrode made of a relatively thicker metal so as to gather an electric current collected by the collecting electrodes. The electrode made of a relatively thicker metal is called a buss bar.

It is also known that a lot of metallic wires as collecting electrodes are connected with a buss bar for gathering an electric current collected by the metallic wires, on a double-coated adhesive sheet, by a laser welding or the like. For example, U.S. Pat. No. 6,121,542 describes a laminated double-coated adhesive sheet containing an acrylic or silicone pressure sensitive adhesive. In Examples, it discloses embodiments wherein a double-coated adhesive sheet having a five-layered laminated structure composed of a silicone pressure sensitive adhesive layer+a polyimide film layer+a silicone pressure sensitive adhesive layer+a polyethylene terephthalate film layer+a silicone pressure sensitive adhesive layer, or a double-coated adhesive sheet having a five-layered laminated structure composed of an acrylic pressure sensitive adhesive layer+a polyimide film layer+an acrylic pressure sensitive adhesive layer+a polyethylene terephthalate film layer+an acrylic pressure sensitive adhesive layer is used. Further, the above U.S. Pat. No. 6,121,542 discloses that an acrylic pressure sensitive adhesive and a silicone pressure sensitive adhesive are particularly preferable, because of excellent durability, heat resistance, and holding power, but a silicone pressure sensitive adhesive is more preferable, in view of a low moisture absorption and an excellent moisture resistance. However, the above U.S. Pat. No. 6,121,542 does not disclose the concrete composition of the acrylic pressure sensitive adhesive or the silicone pressure sensitive adhesive contained in each of the double-coated adhesive sheets, but only discloses “DOUBLE FACE LEW411A” manufactured by TOYO INK MFG, Co., Ltd., which is a double-coated adhesive sheet having a five-layered laminated structure containing a silicone pressure sensitive adhesive, as an example of a double-coated adhesive sheet having the five-layered laminated structure.

### SUMMARY OF THE INVENTION

The present inventors found that the use of the double-coated adhesive sheet (specifically, DOUBLE FACE LEW411A manufactured by TOYO INK MFG, Co., Ltd.) disclosed in U.S. Pat. No. 6,121,542, which has a five-layered laminated structure and contains the silicone pressure sensitive adhesive, caused a disadvantageous problem, when a solar cell module 1 having the structure as shown in FIG. 1 is fabricated.

In the first place, the structure of the solar cell module 1 and the method for producing the same will be briefly explained, referring to FIGS. 1 to 5, and then, the disadvantageous problem as above will be explained.

FIG. 1 is a schematic cross-sectional view of the solar cell module 1. The solar cell module 1 (see FIG. 1) comprises, for example, a photovoltaic device 10 containing an electrically conductive substrate 11, semiconductor layers 12 arranged on one surface of the electrically conductive substrate 11, and so on (see FIG. 5); a molding resin layer 21 embedding the photovoltaic device 10, particularly the surface carrying the semiconductor layers; and a surface-protecting film layer 22 placed on the surface of the molding resin layer 21. The solar cell module 1 can be placed, for example, on a solar cell module base 23 so that the rear side of the substrate 11 is brought into contact therewith. When the photovoltaic device 10 is fabricated, for example, as shown in FIG. 2 (a schematic cross-sectional view), two semiconductor layers 12a, 12b having an interval therebetween are arranged in parallel to each other on the substrate 11, and a double-coated adhesive sheet 13 is inserted into a gap formed between the semiconductor layers 12a, 12b. In this case, the double-coated adhesive sheet 13 has a thickness same as that of each of the semiconductor layers 12a, 12b, and is brought into close contact with the semiconductor layers 12a, 12b so that no gap is formed between the double-coated adhesive sheet 13 and the semiconductor layers 12a, 12b. As a result, a uni-layered structure having a common flat surface on the double-coated adhesive sheet 13 in the center and the semiconductor layers 12a, 12b located in both sides thereof is formed on the surface of the substrate 11. Then, as shown in FIG. 3 (a schematic cross-sectional view) and FIG. 4 (a schematic plan view), a metallic wire 14a is mounted on the surface of one semiconductor layer 12a, and on the surface of the double-coated adhesive sheet 13 adjacent to the surface of one semiconductor layer 12a. Similarly, a metallic wire 14b is mounted on the surface of the other semiconductor layer 12b, and on the surface of the double-coated adhesive sheet 13 adjacent to the surface of the other semiconductor layer 12b. FIG. 4 is a schematic plan view illustrating the state as shown in FIG. 3 and the embodiment wherein each of the line composed of one semiconductor layers (12a), and the line composed of the other semiconductor layers (12b) contains three semiconductor layers 12. Furthermore, FIG. 3 is a cross-sectional view taken along line A-A of FIG. 4. Thus, the photovoltaic element 10A comprising (1) the substrate 11 corresponding to a first electrode, (2) the semiconductor layers 12 contributing to an electric power generation, and (3) the metallic wires 14 corresponding to a second electrode located on a light receiving surface of the semiconductor layers 12 and acting as a collecting electrode, is formed.

Further, as shown in FIG. 5 (a schematic cross-sectional view), a relatively thick metallic buss bar 15 is pressed and adhered to the double-coated adhesive sheet 13 from the upper side thereof in the direction of the arrow A, and then, the metallic wires 14a, 14b are firmly fixed to the buss bar 15 by a laser welding or the like. Thus, the photovoltaic device 10 is formed which comprises the photovoltaic element composed of (1) the substrate 11 corresponding to a first electrode, (2) the semiconductor layers 12 contributing to an electric power generation, and (3) the metallic wires 14 corresponding to a second electrode located on a light receiving surface of the semiconductor layers 12 and acting as a collecting electrode; and (4) the buss bar 15 for gathering the electric current collected by the collecting electrodes and supplying the same to the outside. Alternatively, a photovoltaic device can be fabricated by mounting transparent electrodes as a second electrode on the semiconductor layers 12, and then, forming thereon the metallic wires 14 which act as a collecting electrode. Further, in a photovoltaic device, a transparent and electrically conductive layer can be disposed instead of the transparent electrode or on the transparent electrode, for the purposes of an antireflection and a decrease of a surface resistance.

Subsequently, a solar cell module 1 shown in FIG. 1 can be obtained by embedding the photovoltaic device 10, particularly the surface carrying the semiconductor layers 12 on the substrate 11, with a molding resin, and then, placing a surface-protecting film layer 22 on the molding resin layer 21.

The present inventors found that, when a double-coated adhesive sheet having a five-layered laminated structure containing a silicone pressure sensitive adhesive is used as the double-coated adhesive sheet 13, the molding resin is repelled by the silicone pressure sensitive adhesive layer during the step of embedding the photovoltaic device 10 formed on the substrate 11, with the molding resin, and thus, a sufficient embedding effect cannot be obtained. In addition, the present inventors also found that air bubbles are formed in an interface between the double-coated adhesive sheet and the molding resin due to the fixing procedure of the buss bar 15 and the metallic wires 14 by a laser welding or the like.

The present inventors engaged in an intensive research to solve the above disadvantages of the double-coated adhesive sheet having the five-layered laminated structure containing the silicone pressure sensitive adhesive which was supposed to be most excellent as mentioned in the above U.S. Pat. No. 6,121,542, and found that the disadvantages can be eliminated by an acrylic pressure sensitive adhesive composition containing particular components.

Furthermore, it is manifest that the acrylic pressure sensitive adhesive composition found by the present inventors is different from the acrylic pressure sensitive adhesive described in Example 2 of U.S. Pat. No. 6,121,542, with respect to the components. This is because, as shown in Reference Example as mentioned below, the double-coated adhesive sheet having the five-layered laminated structure containing the acrylic pressure sensitive adhesive described in Example 2 of U.S. Pat. No. 6,121,542 was evaluated to be inferior to the double-coated adhesive sheet having the five-layered laminated structure containing the silicone pressure sensitive adhesive, with respect to the appearance after allowing to stand for 12 hours under conditions of 35° C. and relative humidity of 90% after a laminating procedure, whereas the double-coated adhesive sheet having the five-layered laminated structure containing the acrylic pressure sensitive adhesive composition which the present inventors found was evaluated to be superior over the double-coated adhesive sheet having the five-layered laminated structure containing the silicone pressure sensitive adhesive.

The present invention is based on the above findings.

Therefore, an object of the present invention is to provide an acrylic pressure sensitive adhesive composition, which does not repel a molding resin or dose not generate air bubbles during a molding step in the process for producing a solar cell module.

Further, another object of the present invention is to provide a double-coated adhesive sheet containing the acrylic pressure sensitive adhesive composition.

Furthermore, a still another object of the present invention is to provide a photovoltaic device obtained, using the double-coated adhesive sheet. Other features and advantages of the present invention will be apparent from the following description.

The present invention provides an acrylic pressure sensitive adhesive composition comprising (A) an acrylic polymer having a carboxyl group and (B) a tetrafunctional epoxy compound, without a substantial amount of a tackifying resin, wherein the acrylic polymer (A) has been prepared by copolymerizing

(a) 50% to 80% by weight of butyl acrylate,

(b) 5% to 40% by weight of ethyl acrylate, and

(c) 7% to 22% by weight of at least one carboxyl group-containing compound selected from the group consisting of acrylic acid, methacrylic acid, itaconic acid, crotonic acid, monobutyl maleate and 0-carboxyethyl acrylate; and which has a weight-average molecular weight (Mw) of about 600000 to about 800000 and a glass transition temperature of −35° C. to −10° C.

The present invention can also provide a double-coated adhesive sheet laminated in the following order: (1) a first pressure sensitive adhesive layer, (2) a polyester film layer, (3) a second pressure sensitive adhesive layer, (4) a polyimide film layer, and (5) a third pressure sensitive adhesive layer, wherein each of the first pressure sensitive adhesive layer, the second pressure sensitive adhesive layer and the third pressure sensitive adhesive layer is a layer formed from the acrylic pressure sensitive adhesive composition as above.

Further, the present invention can also provide a photovoltaic device comprising:

(1) a substrate;

(2) at least a pair of photovoltaic elements having an interval therebetween are arranged in parallel to each other on the substrate, wherein each of the photovoltaic elements is a laminate comprising a lower electrode layer which is in contact with the surface of the substrate, a semiconductor layer placed on the lower electrode layer, and a light receiving transparent electrode arranged on the semiconductor layer;

(3) the double-coated adhesive sheet as above, arranged on the surface of the substrate in the gap formed between the pair of the photovoltaic elements, under the conditions that the gap is fully filled with the double-coated adhesive sheet and each photovoltaic element is brought into close contact with the double-coated adhesive sheet, and the double-coated adhesive sheet has a thickness the same as that of each photovoltaic element, wherein the first pressure sensitive adhesive layer is adhered to the substrate, and the third pressure sensitive adhesive layer is in contact with the adjacent light receiving transparent electrode;

(4) one or more pairs of collecting electrodes mounted continuously from the surface of the light receiving transparent electrode to the surface of the double-coated adhesive sheet, and

(5) a buss bar electrically connecting with the collecting electrodes on the surface of the double-coated adhesive sheet, and arranged so that the collecting electrodes are sandwiched between the surface of the double-coated adhesive sheet and the buss bar.

### BRIEF DESCRIPTION OF THE DRAWINGS

FIG. 1 is a schematic cross-sectional view of a solar cell module which can be fabricated, using the double-coated adhesive sheet according to present invention.

FIG. 2 is a schematic cross-sectional view illustrating an early step in the production of the solar cell module shown in FIG. 1.

FIG. 3 is a schematic cross-sectional view illustrating a step which follows the step of FIG. 2.

FIG. 4 is a schematic plan view of the state shown in FIG. 3.

FIG. 5 is a schematic cross-sectional view illustrating a step which follows the step of FIG. 3.

FIG. 6 is a schematic cross-sectional view of the double-coated adhesive sheet according to the present invention.

FIG. 7 is a schematic cross-sectional view illustrating the sate that a laminated sample for evaluating appropriateness for molding is adhered to a bottom surface of a bat.

FIG. 8 is a schematic cross-sectional view illustrating the state that bubbles are generated in a test for evaluating appropriateness for molding.

FIG. 9 is a schematic cross-sectional view illustrating the state that a flat surface is formed in a test for evaluating appropriateness for molding.

FIG. 10 is a schematic cross-sectional view illustrating the state that groove structures are formed in a test for evaluating appropriateness for molding.

### DESCRIPTION OF PREFERRED EMBODIMENTS

### Acrylic Pressure Sensitive Adhesive Composition

An acrylic pressure sensitive adhesive composition according to the present invention comprises (A) an acrylic polymer having a carboxyl group and (B) a tetrafunctional epoxy compound, without a substantial amount of a tackifying resin. In the present specification, the expression “without a substantial amount of a tackifying resin” means that a tackifying resin, for example, a known tackifying resin, such as a terpene resin, an aliphatic petroleum resin, an aromatic petroleum resin, a coumarone-indene resin, a phenolic resin, a terpene-phenolic resin, a rosin derivative (such as rosin, polymerized rosin, hydrogenerated rosin, or an ester thereof with glycerine or pentaerythritol, or a dimer resinate) is not contained in such an amount that the function thereof is exerted. The acrylic polymer having a carboxyl group has a weight-average molecular weight (Mw) of about 600 thousands to about 800 thousands, preferably about 600 thousands to about 700 thousands, and a glass transition temperature (Tg) of −35° C. to −10° C., preferably −32° C. to −20° C.

If the weight-average molecular weight (Mw) is less than about 600 thousands, a heat resistance is lowered. If the weight-average molecular weight (Mw) is more than about 800 thousands, an adhesive strength is lowered. Further, if the glass transition temperature is less than −35° C., the adhesive composition is liable to ooze from an edge. If the glass transition temperature is more than −10° C., an adhesive strength becomes insufficient and consequently it may cause a peeling-off.

The acrylic polymer (A) is prepared by copolymerizing

(a) 50% to 80% (preferably 65% to 75%) by weight of butyl acrylate,

(b) 5% to 40% (preferably 15 to 25%) by weight of ethyl acrylate 5 to 40% by weight,

(c) 7% to 22% (preferably 10% to 15%) by weight of at least one carboxyl group-containing compound selected from the group consisting of acrylic acid, methacrylic acid, itaconic acid, crotonic acid, monobutyl maleate and 0-carboxyethyl acrylate.

If the ratio of butyl acrylate (a) in the acrylic polymer (A) is less than 50% by weight, an adhesive strength at an early stage and an endurance adhesive strength may be lowered. If the ratio of butyl acrylate (a) in the acrylic polymer (A) is more than 80% by weight, a cohesive strength may be lowered.

If the ratio of ethyl acrylate (b) in the acrylic polymer (A) is less than 5% by weight, a cohesive strength and a holding function may be lowered. If the ratio of ethyl acrylate (b) to the acrylic polymer (A) is more than 40% by weight, an adhesive strength at an early stage may be lowered.

If the ratio of the carboxyl group-containing compound (c) in the acrylic polymer (A) is less than 7% by weight, a heat resistance and a fitting adhesiveness with metal may be lowered. If the ratio of the carboxyl group-containing compound (c) in the acrylic polymer (A) is more than 22% by weight, hygroscopicity may become higher, and bubbles may be formed in a molding.

The carboxyl group-containing compound may be used alone or in combination of two or more compounds. However, it is preferable to use one of acrylic acid or methacrylic acid, and more preferable to use acrylic acid as a sole compound.

The tetrafunctional epoxy compound is used as a cross-linking agent. Any compounds exhibiting a function of a cross-linking agent can be used as the tetrafunctional epoxy compound. Specifically, examples of the tetrafunctional epoxy compound are a glycidylamine-based epoxy resin, such as TEDRAD X manufactured by Mitsubishi Chemical Corporation, or a tetraphenylolethane-based epoxy resin, such as 1031S manufactured by Japan Epoxy Resins Co., Ltd.

In the acrylic pressure sensitive adhesive composition according to the present invention, the tetrafunctional epoxy compound (B) is contained in an amount of preferably 0.1 to 3.0 parts by weight, more preferably 0.5 to 1.5 parts by weight, with respect to 100 parts by weight of the carboxyl group-containing acrylic polymer.

A moisture absorption rate of the acrylic pressure sensitive adhesive composition according to the present invention is not limited, but is preferably 0.0% to 1.5%, more preferably 0.01 to 1.0%, when the acrylic pressure sensitive adhesive composition is allowed to stand for 12 hours under the conditions of 40° C. and relative humidity of 80%. When the acrylic pressure sensitive adhesive composition has the moisture absorption rate as above, a defective appearance which may be caused in a resin-coating step for the photovoltaic device can be prevented.

### Double-Coated Adhesive Sheet

The double-coated adhesive sheet having a five-layered laminated structure according to the present invention can be fabricated from the acrylic pressure sensitive adhesive composition according to the present invention. The double-coated adhesive sheet according to the present invention has the structure of the lamination in the following order: (1) a first pressure sensitive adhesive layer, (2) a polyester film layer, (3) a second pressure sensitive adhesive layer, (4) a polyimide film layer, and (5) a third pressure sensitive adhesive layer. Further, each of the first pressure sensitive adhesive layer, the second pressure sensitive adhesive layer, and the third pressure sensitive adhesive layer is formed from the acrylic pressure sensitive adhesive composition according to the present invention, respectively.

FIG. 6 is a schematic cross-sectional view illustrating the structure of the embodiment wherein the double-coated adhesive sheet 30 having a five-layered laminated structure according to the present invention is formed on the release sheet 36. As shown in FIG. 6, the double-coated adhesive sheet 30 according to the present invention contains the first pressure sensitive adhesive layer 31 as one outermost layer, and the polyester film layer 32 under the first pressure sensitive adhesive layer 31. The polyester film layer 32 is adhered to the polyimide film layer 34 via the second pressure sensitive adhesive layer 33, and the third pressure sensitive adhesive layer 35 is placed on the opposite side of the polyimide film layer 34 as the other outermost layer. The double-coated adhesive sheet 30 as shown in FIG. 6 can be protected, for example, with a release sheet 36 placed on the third pressure sensitive adhesive layer 35, and stored in the form of a wound roll. The double-coated adhesive sheet according to the present invention can be easily rewound from the wound roll as the stored form, and can be easily removed from the release sheet at a high or low speed.

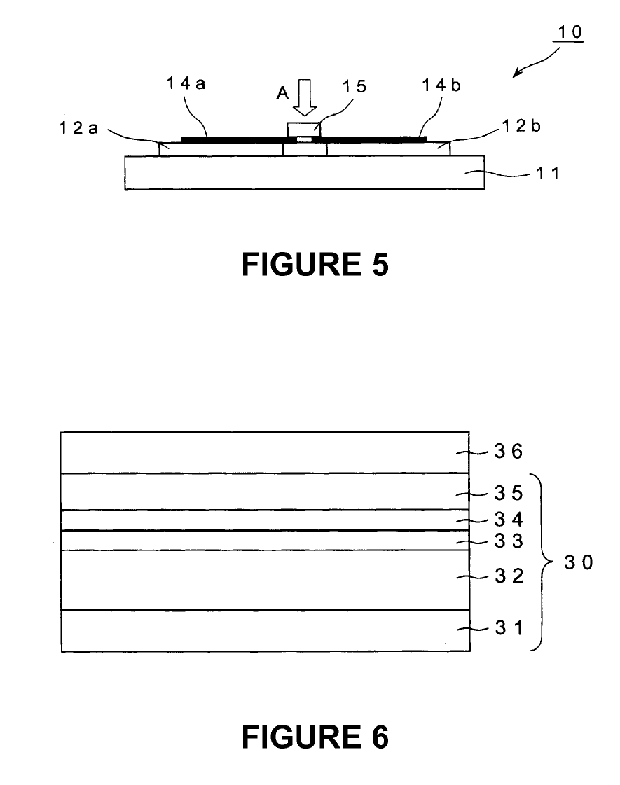

The double-coated adhesive sheet according to the present invention is used as the double-coated adhesive sheet 13, particularly when the photovoltaic device 10 as shown in FIG. 5 is fabricated. Therefore, the double-coated adhesive sheet according to the present invention has a thickness the same as that of the semiconductor layers 12 (12a, 12b). The semiconductor layers used in the photovoltaic device generally have a thickness of 200 to 300 μm. Therefore, the coated adhesive sheet according to the present invention also generally has a thickness of 200 to 300 μm. Furthermore, for example, when the photovoltaic device 10 as shown in FIG. 5 is fabricated by using the double-coated adhesive sheet according to the present invention, the first pressure sensitive adhesive layer 31 is adhered on the substrate 11 corresponding to the first electrode. Therefore, the surface of the third pressure sensitive adhesive layer 35 faces to the direction same as that of the surface of the light receiving surface in the semiconductor layers 12, and the surface of the third pressure sensitive adhesive layer 35 is in contact with the metallic wires 14 corresponding to the second electrode and acting as the collecting electrode. The arrangement as above is more appropriate in view of a heat resistance of the whole double-coated adhesive sheet 13, because the polyimide film layer 34 having an excellent heat stability is located near to the surface where the welding of the metallic wires 14 and the buss bar 15 is carried out.

In the double-coated adhesive sheet according to the present invention, the ratio (T2/T1) of the total thickness (T2) of the polyester film layer and the polyimide film layer, to the total thickness (T1) of the first pressure sensitive adhesive layer, the second pressure sensitive adhesive layer, and the third pressure sensitive adhesive layer is preferably about 0.3 to 1.5, more preferably 0.6 to 1.0. If the ratio (T2/T1) is less than 0.3, an adhesive strength is lowered. If the ratio (T2/T1) is more than 1.5, the adhesive composition is liable to ooze from an edge.

In the double-coated adhesive sheet according to the present invention, the thickness of the first pressure sensitive adhesive layer is preferably about 10% to about 40%, more preferably about 20% to about 30%, with respect to the entire thickness of the double-coated adhesive sheet. If the thickness of the first pressure sensitive adhesive layer is less than 10%, an adhesive strength is lowered. If the thickness of the first pressure sensitive adhesive layer is more than 40%, the adhesive composition is liable to ooze from an edge.

In the double-coated adhesive sheet according to the present invention, the thickness of the second pressure sensitive adhesive layer is preferably about 3% to about 40%, more preferably about 5% to about 20%, with respect to the entire thickness of the double-coated adhesive sheet. If the thickness of the second pressure sensitive adhesive layer is less than 3%, the peeling-off of two layers adhered thereto is liable to occur. If the thickness of the second pressure sensitive adhesive layer is more than 40%, the adhesive composition is liable to ooze from an edge.

In the double-coated adhesive sheet according to the present invention, the thickness of the third pressure sensitive adhesive layer is preferably about 10% to about 40%, more preferably about 20% to about 30%, with respect to the entire thickness of the double-coated adhesive sheet according to the present invention. If the thickness of the third pressure sensitive adhesive layer is less than 10%, an adhesive strength is lowered. If the thickness of the third pressure sensitive adhesive layer is more than 40%, the adhesive composition is liable to ooze from an edge.

In the double-coated adhesive sheet according to the present invention, the thickness of the polyester film layer is preferably about 15% to about 50%, more preferably about 25% to about 40%, with respect to the entire thickness of the double-coated adhesive sheet. If the thickness of the polyester film layer is less than 15%, an insulating property may be insufficient. If the thickness of the polyester film layer is more than 50%, shrinkage upon heated may be increased. A biaxially-stretched film can be used, for example, as polyester.

In the double-coated adhesive sheet according to the present invention, the thickness of the polyimide film layer is preferably about 3% to about 40%, more preferably about 5% to about 20%, with respect to the entire thickness of the double-coated adhesive sheet. If the thickness of the polyimide film layer is less than 3%, an insulating property may be insufficient. If the thickness of the polyimide film layer is more than 40%, a moisture absorption rate may become too high.

Regarding the first pressure sensitive adhesive layer in the double-coated adhesive sheet according to the present invention, an adhesive strength thereof at an early stage (against a stainless steel plate: peeling angle=180°: peeling rate=300 mm/min) is preferably 5 to 20 N/inch, more preferably 8 to 15 N/inch.

Regarding the first pressure sensitive adhesive layer in the double-coated adhesive sheet according to the present invention, an adhesive strength (against a stainless steel plate: peeling angle=180°: peeling rate=300 mm/min) after allowing to stand for 1000 hours under conditions of 85° C. and relative humidity (RH) of 85% is preferably 10 to 30 N/inch, more preferably 15 to 25 N/inch.

Regarding the first pressure sensitive adhesive layer in the double-coated adhesive sheet according to the present invention, an adhesive strength (against a stainless steel plate: peeling angle=1800: peeling rate=300 mm/min) after allowing to stand for 1000 hours under condition of 150° C. is preferably 15 to 30 N/inch, more preferably 17 to 27 N/inch.

### Photovoltaic Device

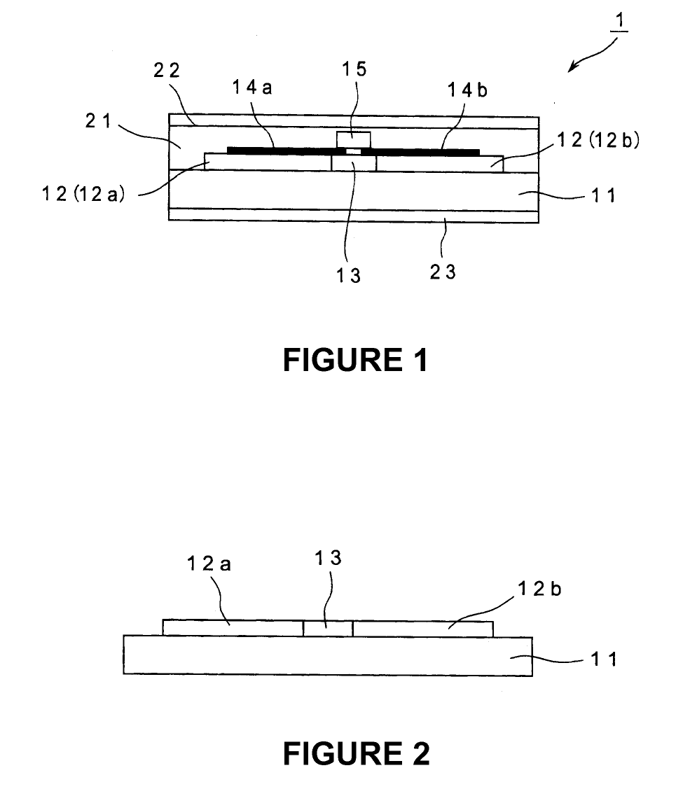

The double-coated adhesive sheet according to the present invention is used as the double-coated adhesive sheet 13, for example, when the photovoltaic device 10 as shown in FIG. 5 is fabricated. The photovoltaic device 10 contains the photovoltaic element 10A. Generally, as described above, a photovoltaic element is a laminate of a lower electrode, a semiconductor layer contributing to an electric power generation and a light receiving transparent electrode, and the lower electrode is brought into contact with the substrate. When the substrate has an electrically conductive surface or the substrate is made of an electrically conductive material, it is not necessary to provide a lower electrode because the electrically conductive surface or the electrically conductive substrate acts as the lower electrode. Further, instead of the light receiving transparent electrode, the metallic wire 14 can be used. In this case, the metallic wire 14 has a function of a second electrode in a light receiving surface and also acts as the collecting electrode. FIGS. 1 to 5 illustrate the embodiment wherein the electrically conductive substrate 11 is used as a lower electrode, and a light receiving transparent electrode is not arranged as the second electrode, but the metallic wire 14 is used as the second electrode and as the collecting electrode. The photovoltaic device according to the present invention will be described with reference to the embodiment as shown in FIGS. 1 to 5.

### Lower Electrode

The lower electrode is mounted on the rear side of the semiconductor layer. The lower electrode may be formed from a metallic layer formed, for example, by a screen printing or a vacuum deposition. The metal material constituting the metallic layer may be properly selected from metals capable of providing a good ohmic contact with the semiconductor.

For example, when the semiconductor layer of an amorphous silicon film is used, it is necessary to use a substrate. As the substrate, an electrically conductive substrate or an electrically insulating substrate is used. In this case, the lower electrode is deposited on the substrate.

As the lower electrode, a metallic substrate of stainless steel or aluminum may be preferably used. Further, the lower electrode may be prepared by evaporating a material such as Cr, Al, or Ag on an electrically insulating substrate of glass, polymer resin, ceramics or the like. When a crystal silicon photovoltaic element is used as the photovoltaic element, the lower electrode may be formed by a screen printing of an Ag-paste, without the substrate.

### Semiconductor Layer

The semiconductor layer must have a structure with a semiconductor junction, such as a pn junction, a pin junction, a Schottky junction or the like. Specifically, in the semiconductor layer, a semiconductor material of an element belonging to the Group IV of the periodic table, such as single crystalline silicon, polycrystalline silicon, thin-film polycrystalline silicon, or amorphous silicon; a semiconductor conductor material of an elements belonging to the Groups II and VI of the periodic table, such as CdS or CdTe; or a semiconductor material of element belonging to the Groups III and V of the periodic table, such as GaAs, may be preferably used. Not only a single cell but also a tandem cell or a triple cell wherein plural pn or pin junctions are accumulated may be preferably used. Specifically, the tandem cell structure may be, for example, an accumulated cell structure comprising a pin top cell having an i-layer of an a-Si and a pin bottom cell having an i-layer of an a-Si, an accumulated cell structure comprising a pin top cell having an i-layer of an a-Si and a pin bottom cell having an i-layer of an a-SiGe, or an accumulated cell structure comprising a pin top cell having an i-layer of an a-Si and a pin bottom cell of a thin-layered polycrystalline pn structure. The triple cell structure may be, for example, an accumulated cell structure comprising a pin top cell having an i-layer of an a-Si, a pin middle cell having an i-layer of an a-Si and a pin bottom cell having an i-layer of an a-SiGe; or an accumulated cell structure comprising a pin top cell having an i-layer of an a-Si, a pin middle cell having an i-layer of an a-SiGe, and a pin bottom cell having an i-layer of an a-SiGe.

### Transparent and Electrically Conductive Layer

If necessary, it is possible to arrange a transparent and electrically conductive layer between the light receiving surface of the semiconductor layer and the metallic wires, for the purpose of preventing a light reflection and reducing an electrical surface resistance. As the transparent and electrically conductive layer, known materials such as ITO, SnO₂, In₂O₃ or the like may be preferably used.

### Metallic Wire

As the metallic wire used as the collecting electrode (and also as the second receiving electrode, as the case may be), a material having a low electric resistance, such as Cu, Ag, Au, Pt, Al, Mo, or W may be preferably used. The metallic wire may be also formed from alloys of these metals. Further, if desired, a thin metallic surface layer may be formed on the surface of the metallic wire for preventing the metallic wire from being corroded or oxidized, improving an adhesive strength of the metallic wire to an electrically conductive resin, or improving an electrical conductivity of the metallic wire. For the metallic surface layer, a noble metal such as Ag, Pd, Ag—Pd alloy or Au which is difficult to be corroded, or a metal such as Ni or Sn which has an excellent corrosion resistance is preferable. The metallic surface layer may be formed preferably by a plating or cladding method. Alternatively, an electrically conductive resin composition prepared by dispersing the above metal as a filler in a resin may be coated. In this case, the coat layer may have a desired thickness. For instance, when the metallic wire has a circular cross section, the thickness thereof is preferably 1 to 10% of the diameter.

The metallic wire has preferably a circular cross section, but may have a rectangular cross section. The sectional shape may be appropriately selected. The diameter of the metallic wire having a circular cross section is designed and selected so that the sum of an electric resistance loss and a shadow loss is minimized. Specifically, the diameter is designed preferably in the range of 25 μm to 1 mm, more preferably in the range of 25 μm to 200 μm to obtain an efficient photovoltaic device. If the diameter is less than 25 μm, the metallic wire is liable to be cut or an electricity loss is increased. If the diameter is more than 200 μm, a shadow loss is increased, or an irregular structure on the surface of the photovoltaic element is enlarged and thus, it becomes necessary to thicken a filler such as EVA when the resin sealing such as lamination is performed.

The metallic wire may be prepared by a conventional wire drawing machine capable of producing a metallic wire having a desired diameter. The metallic wire after passed through the wire drawing machine is a hard material, but the metallic wire may be used after softened by a known annealing treatment to desired properties such as easiness to elongation or bending.

### Buss Bar

The buss bar used in the present invention is formed from a metallic or alloy material having a low electric resistance. Specific examples of such metallic material are metals such as Cu, Ag, Au, Pt, Al, Sn, Pb or Ni, or alloys of these metals. If necessary, a thin metallic surface layer may be formed on the surface of the buss bar for preventing the buss bar from being corroded or oxidized, improving an adhesive strength of the buss bar to an electrically conductive resin, or improving an electrical conductivity of the buss bar. Alternatively, an electrically conductive paste may be applied on at least a part of the surface of the buss bar to electrically connect the buss bar to the metallic wire. The buss bar may be in the form of a belt foil or a wire.

### Electrically Conductive Adhesive

The electrically conductive adhesive can be used to adhere the metallic wire to the surface of the photovoltaic element (the surface of the light receiving transparent electrode or the surface of the semiconductor layer) and the buss bar.

The bonding method comprises coating an entire or part of the surface area of the metallic wire with the electrically conductive adhesive, and then, adhering by heating and/or pressing. Alternatively, the buss bar may be adhered to the metallic wire by applying the electrically conductive adhesive on the buss bar in advance, and then, heating and/or pressing. The electrically conductive adhesive can be obtained, for example, by mixing conducting particles and polymeric resins. A preferable binder resin is a polymer resin which enables to easily form a coating film on the surface of the metallic wire, and has excellent workability, flexibility and antiweatherability. Such a polymer resin is preferably, for example, a thermosetting resin or a thermoplastic resin. Specific examples of the thermosetting resin are epoxy resins, urethane resins, phenol resins, polyvinyl formals, alkyd resins, and modified resins thereof. Of these, urethane resins are used as an insulating coating material for an enameled wire, and have excellent flexibility and productivity, and thus are preferable. Specific examples of the thermoplastic resin are polyamideimide resins, melamine resins, butyrals, phenoxy resins, polyimide resins, fluoro resins, acrylic resins, styrenes, and polyesters.

The electrically conductive particles are pigments for imparting an electrically conductivity. Specific examples of such pigment are preferably graphite, carbon black, a metal oxide such as In₂O₃, TiO₂, SnO₂, ITO or ZnO, or an oxide semiconductor material prepared by adding a dopant to the above material. The electrically conductive particle must have a particle size smaller than the thickness of a coating layer formed. However, the particle size cannot be too small to obtain a desired specific resistance, because of an excessive resistance between particles brought into contact with each other. Under the circumstances, the electrically conductive particles preferably have an average particle size in the range of 0.02 μm to 15 μm. The electrically conductive particles are mixed with the polymer resin at an appropriate mixing ratio so that a desired specific resistance can be obtained. If the content of the electrically conductive particles is increased, a low specific resistance can be obtained, but the ratio of the resin is lowered and thus, the stability of the coated film is lowered. If the content of the resin is increased, the electrically conductive particles are lesser brought into contact with each other, the resistance is increased. Therefore, a preferable ratio is appropriately selected in view of the combination of the electrically conductive particles, the polymer resin, and the desired physical properties. Specifically, a good specific resistance can be obtained when the electrically conductive particles are contained in the range of about 5% to 95% by volume.

It is necessary that the electrically conductive adhesive has a specific resistance which can be disregarded in collecting an electric current generated by the photovoltaic element, and has a coating thickness which does not cause a shunt due to a migration of a metal ion from the metallic wire. Specifically, a specific resistance is preferably in the range of 0.01 Ω·cm to 100 Ω·cm. If the specific resistance is less than 0.01 Ω·cm, a barrier function for preventing the shunt is deteriorated. If the specific resistance is more than 100 Ω·cm, the loss in the electric resistance is increased. The electrically conductive particles and the polymer resin may be mixed by a conventional dispersing apparatus such as a triple roll mill, a paint shaker, or a beads mill. If desired, a known dispersing agent can be added to facilitate the dispersion. Further, during or after the dispersing procedure, it is possible to dilute the electrically conductive resin by adding an appropriate solvent for adjusting the viscosity thereof.

### Fabrication of Photovoltaic Device

The photovoltaic device can be fabricated by adhering the metallic wires under the buss bar and on the semiconductor layer of the photovoltaic element or a transparent and electrically conductive layer. The above adhering method is preferably carried out by heating and/or pressing. The heating temperature is preferably more than the temperature at which the electrically conductive adhesive is softened, and adhered to the buss bar and/or the surface of the photovoltaic element. The pressure is preferably a pressure at which an electrically conductive adhesive is moderately deformed, but the photovoltaic element is not destroyed. Specifically, the pressure is preferably from 0.1 kg/cm² to 1.0 kg/cm², for example, for a thin film photovoltaic element such as an amorphous silicon.

In the adhering method, the electrically conductive adhesive is preferably applied and coated over the edge portion or the whole of the metallic wires in advance. When the electrically conductive adhesive is applied all over the metallic wires in the longitudinal direction, the connection of the metallic wires and the buss bar, and the connection of the metallic wires and the surface of the photovoltaic element can be carried out at the same time, and consequently a working time can be greatly shortened. The electrically conductive adhesive may be applied to the buss bar, or to both the metallic wires and the buss bar.

The metallic wires may be adhered to the surface of the photovoltaic element by forming lines or dots of the electroconductive adhesive by a screen printing or the like, and then mounting and adhering the wires thereon.

The thermoplastic electroconductive adhesive is softened by heating. When the thermosetting resin is used, however, the thermosetting resin is applied to the wires and/or the buss bar or printed on the photovoltaic element without carrying out a curing reaction, while only drying by removing the solvent. It can be cured by heating when adhesion is necessary.

When the photovoltaic device 10 of the embodiment as shown in FIGS. 1 to 5 is fabricated, a pair of the semiconductor layers 12a, 12b having an interval therebetween are arranged in parallel to each other on the electrically conductive substrate 11 which acts as a lower electrode, as shown in FIG. 2. For example, as shown in FIG. 4, plural lines of the semiconductor layers 12a having intervals therebetween and plural lines of the semiconductor layers 12b having intervals therebetween can be arranged in parallel to each other. Further, when the substrate 11 is made of an insulating material, an electrically conductive layer may be arranged on the surface of the substrata to form a lower electrode. Alternatively, before a pair of the semiconductor layers 12a, 12b are arranged, a pair of the lower electrode layers having interval therebetween may be arranged in parallel to each other on the electrically insulating substrate, then a pair of the semiconductor layers 12a, 12b having interval therebetween may be arranged in parallel to each other on the lower electrode layers.

Subsequently, as shown in FIG. 2, the double-coated adhesive sheet 13 is inserted into a gap formed between the semiconductor layers 12a, 12b. In this case, the double-coated adhesive sheet 13 has a thickness same as that of each of the semiconductor layers 12a, 12b, and is brought into close contact with the semiconductor layers 12a, 12b so that no gap is formed between the double-coated adhesive sheet 13 and the semiconductor layers 12a, 12b. As a result, a uni-layered structure having a common flat surface on the double-coated adhesive sheet 13 in the center and the semiconductor layers 12a, 12b located in both sides thereof is formed on the surface of the substrate 11. Further, in the double-coated adhesive sheet 13, the first pressure sensitive adhesive layer 31 is adhered to the substrate 11, and the third pressure sensitive adhesive layer 35 is brought into contact with the adjacent surfaces of the semiconductor layers 12a, 12b. When a laminate of the semiconductor layer and the light receiving transparent electrode is formed on the substrate, or the photovoltaic element (a laminate made of the lower electrode layer, the semiconductor layer and the light receiving transparent electrode) is formed on the substrate, the laminate has the thickness same as that of the double-coated adhesive sheet 13, and is brought into close contact with the double-coated adhesive sheet 13 so that no gap is formed between the laminate and the double-coated adhesive sheet 13.

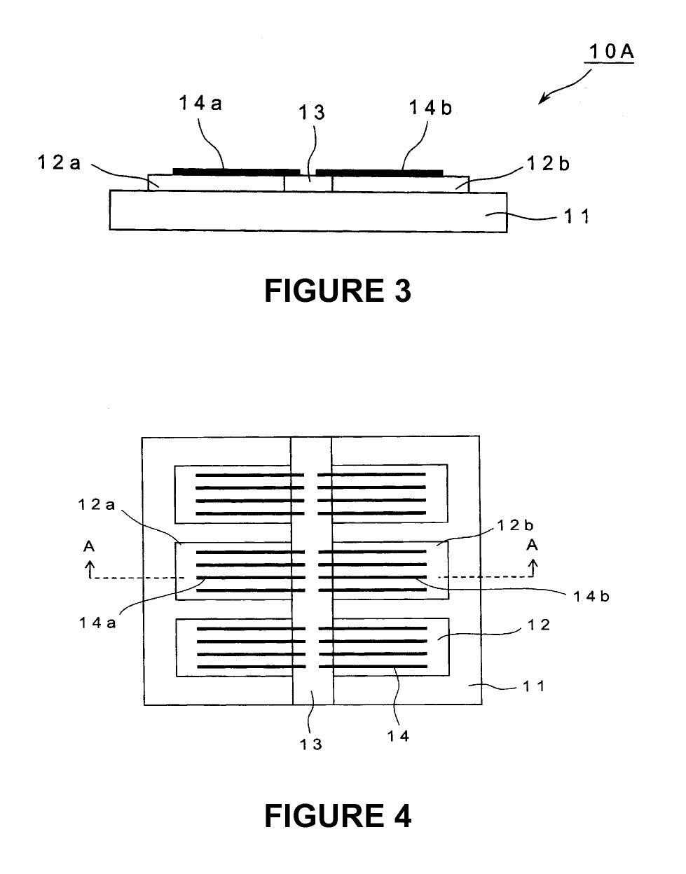

Then, as shown in FIGS. 3 and 4, the metallic wire 14a is mounted continuously from the surface of one semiconductor layer 12a to the surface adjacent thereto of the double-coated adhesive sheet 13. Similarly, the metallic wire 14b is mounted continuously from the surface of the other semiconductor layer 12b to the surface adjacent thereto of the double-coated adhesive sheet 13. Since the metallic wires 14a, 14b act as a collecting electrode, the wires cover the entire surface of the semiconductor layers 12a, 12b, and have the form of an elongated thin comb to minimize a shadow loss. One edge of each of the metallic wires 14a, 14b extends to the edge area opposite to the double-coated adhesive sheet 13 in the semiconductor layers 12a, 12b. The other edge of each of metallic wires 14a, 14b extends to the position near to the central area in the surface of the double-coated adhesive sheet 13, where the wires may not contact with each other, or may contact with each other. As described above, since each of the metallic wires 14a, 14b must be mounted continuously from the surface of the semiconductor layers 12a, 12b to the surface of the double-coated adhesive sheet 13, it is necessary that the thickness of the semiconductor layers 12a, 12b are exactly same as the thickness of the double-coated adhesive sheet 13.

When the light receiving transparent electrode is arranged on the semiconductor layer, or the transparent and electrically conductive layer is arranged on the semiconductor layer, instead of or in addition to the light receiving transparent electrode, the metallic wires 14a, 14b can be arranged on the light receiving transparent electrode, or the transparent and electrically conductive layer, by the same procedure described above.

Thereafter, as shown in FIG. 5, a relatively thick metallic buss bar 15 is pressed and adhered to the double-coated adhesive sheet 13 from the upper side thereof in the direction of the arrow A, and then, the metallic wires 14a, 14b are firmly fixed to the buss bar 15 by a laser welding or the like, and at the same time, the metallic wires 14a, 14b are firmly fixed to the semiconductor layers 12a, 12b, or the light receiving transparent electrode or the transparent and electrically conductive layer.

Thus, the photovoltaic device 10 according to the present invention can be fabricated.

### Molding Resin Layer

Subsequently, the photovoltaic device is preferably embedded with a molding resin. For example, EVA (ethylene vinyl acetate), EEA (ethylene ethyl acrylate) or the like can be preferably used as a resin for forming the molding resin layer 21, in view of the adhesive property to a solar cell, the weatherability, and the buffer effect.

### Surface-Protecting Layer

Further, a surface-protecting layer is preferably arranged on the molding resin layer 21. As the surface-protecting layer 22, a fluorine-based resin film layer can be used to obtain a weight reduction and a flexibility of a module. The fluorine-based resin is, for example, a copolymer ETFE of tetrafluoroethylene (manufactured by Du Pont; Tefzel), polyvinyl fluoride (manufactured by Du Pont; Tedlar) or the like. Furthermore, the weatherability may be enhanced by adding a UV absorber to the resins.

A method of molding by the resin-sealed can be carried out, for example, by bonding with heating and pressing under vacuum, using a device such as a vacuum laminator. When a translucent substrate such as glass is used as the surface-protecting film layer, a photovoltaic device can be sealed with a resin, and the rear side can be protected by a fluorocarbon resin or a film such as PET.

### EXAMPLES

The present invention now will be further explained by, but is by no means limited to, the following Examples.

### Example 1

### Preparation of Pressure Sensitive Adhesive Composition

In ethyl acetate and toluene, 70% by weight of butyl acrylate, 20% by weight of ethyl acrylate and 10% by weight of acrylic acid were copolymerized to obtain an acrylic polymer solution having a weight-average molecular weight of 650 thousands and a glass transition temperature (theoretical value) of about −30° C. With respect to a solid content of 100 parts by weight of the acrylic polymer solution, 0.8 part by weight of N,N,N′,N′-tetraglycidyl-m-xylylenediamine (TETRAD-X: manufactured by MITSUBISHI GAS CHEMICAL COMPANY, INC.) as a tetrafunctional epoxy compound was incorporated to obtain an acrylic pressure sensitive adhesive composition.

The glass transition temperature (theoretical value) was calculated from glass transition temperatures (Tg) of the homopolymers formed from monomers, i.e., the glass transition temperature (−52° C.) of butyl acrylate, the glass transition temperature (−22° C.) of ethyl acrylate, the glass transition temperature (105° C.) of acrylic acid, and a molar ratio of those monomers, by the following formula (I):

(−52×0.7)+(−22×0.2)+(105×0.1)=−30.3.

Further, in Table 1, the following abbreviations are used for the monomers:

BA: butyl acrylate (Tg of homopolymer: −52° C.)

EA: ethyl acrylate (Tg of homopolymer: −22° C.)

AA: acrylic acid (Tg of homopolymer: 105° C.)

2EHA: 2-ethylhexyl acrylate (Tg of homopolymer: −70° C.)

MA: methyl acrylate (Tg of homopolymer: 8° C.)

2HEMA: 2-hydroxyethyl methacrylate (Tg of homopolymer: 55° C.).

### Example 2

### Fabrication of Double-Coated Adhesive Sheet

### (1) First Step

The acrylic pressure sensitive adhesive composition prepared in Example 1 was coated on one side of a polyethylene terephthalate (PET) film having a thickness of 75 μm, and then dried to form an adhesive layer [corresponding to a second pressure sensitive adhesive layer] having a thickness of 25 μm. Thereafter, a polyimide (PI) film having a thickness of 25 μm was laid on the second pressure sensitive adhesive layer to obtain a three-layered laminate comprising the PET film layer (thickness=75 μm)/the second pressure sensitive adhesive layer (thickness=25 μm)/the PI film layer (thickness=25 μm).

### (2) Second Step

The acrylic pressure sensitive adhesive composition prepared in Example 1 was coated on one side of a first release sheet, and then dried to form an adhesive layer [corresponding to a third pressure sensitive adhesive layer] having a thickness of 50 μm.

Thereafter, the polyimide surface of the three-layered laminate obtained in the above first step (1) was laid on the third pressure sensitive adhesive layer to obtain a four-layered laminate (on the first release sheet) comprising PET film layer (thickness=75 μm)/a second pressure sensitive adhesive layer (thickness=25 μm)/a PI film layer (thickness=25 μm)/a third pressure sensitive adhesive layer (thickness=50 μm)/the first release sheet.

### (3) Third Step

The acrylic pressure sensitive adhesive composition prepared in Example 1 was coated on one side of the second release sheet, and then dried to form an adhesive layer [corresponding to a first pressure sensitive adhesive layer] having a thickness of 50 μm. Thereafter, a polyethylene terephthalate surface of the four-layered laminate (on the first release sheet) obtained in the above second step (2) was laid on the first pressure sensitive adhesive layer to obtain a double-coated adhesive sheet composed of a five-layered laminate (between the first release sheet and the second release sheet) comprising the second release sheet/the first pressure sensitive adhesive layer (thickness=50 μm)/the PET film layer (thickness=75 μm)/the second pressure sensitive adhesive layer (thickness=25 μm)/the PI film layer (thickness=25 μm)/the third pressure sensitive adhesive layer (thickness=50 μm)/the first release sheet.

### Evaluation of Properties

### 1. Adhesive Strength to Stainless Steel Plate and Change in Appearance

### (1) Fabrication of Adhesion Sample

Under conditions of 23° C. and relative humidity (RH) of 50%, the first release sheet was removed from the double-coated adhesive sheet fabricated in Example 2 to expose the third pressure sensitive adhesive layer. The polyimide film having the thickness of 25 μm was adhered to the exposed third pressure sensitive adhesive layer to cover the third pressure sensitive adhesive layer. The resulting laminate was cut to the size of 25 mm in width to obtain a polyimide laminated sample.

Thereafter, under conditions of 23° C. and relative humidity (RH) of 50%, the second release sheet was removed from the polyimide laminated sample to expose the first pressure sensitive adhesive layer. The exposed first pressure sensitive adhesive layer was laid on a stainless steel plate, and then, adhered thereto by reciprocating a roller having 2 kg once over the side of the polyimide film covering the third pressure sensitive adhesive layer to thereby obtain an adhesion sample on the stainless steel plate composed of the stainless steel plate/the first pressure sensitive adhesive layer/the PET film layer/the second pressure sensitive adhesive layer/the PI film layer/the third pressure sensitive adhesive layer/the PI film layer.

### (2) Adhesive Strength at an Early Stage

After 30 minutes from the adhering to the stainless steel plate, the adhesion sample was removed at a peeling angle of 180° and a peeling rate at 300 mm/min to determine an adhesive strength at an early stage for an interface between the stainless steel plate and the first pressure sensitive adhesive layer.

### (3) Adhesive Strength After High Temperature and High Humidity, and Change in Appearance

After adhered to the stainless steel plate, the adhesion sample on the stainless steel plate was allowed to stand for 1000 hours under the conditions of 85° C. and relative humidity (RH) of 85%. Thereafter, the adhesion sample was turned back under the conditions of 23° C. and relative humidity (RH) of 50%, and then, the appearance was visually observed. Under the same conditions, the adhesion sample was removed at a peeling angle of 180° and a peeling rate of 300 mm/min to determine the adhesive strength of an interface between the stainless steel plate and the first pressure sensitive adhesive layer.

### (4) Adhesive Strength After High Temperature and Change in Appearance

After adhered to the stainless steel plate, the adhesion sample on the stainless steel plate was allowed to stand at 150° C. for 1000 hours. Thereafter, the adhesion sample was turned back under the conditions of 23° C. and relative humidity (RH) of 50%, and the appearance was visually observed. Under the same conditions, the adhesion sample was removed from the stainless steel plate at a peeling angle of 180° and a peeling rate of 300 mm/min to determine the adhesion of an interface between stainless steel plate and the first pressure sensitive adhesive layer.

### 2. Appropriateness for Molding

### (1) Fabrication of Evaluation Sample

Under the conditions of 23° C. and relative humidity (RH) of 50%, the first release sheet was removed from the double-coated adhesive sheet fabricated in Example 2 to expose the third pressure sensitive adhesive layer. A copper foil was laid on the exposed surface of the third pressure sensitive adhesive layer. After a roller with 2 kg was reciprocated from the side of the copper foil, the resulting laminate was cut to the size of 50 mm×50 mm to obtain a copper foil laminated sample.

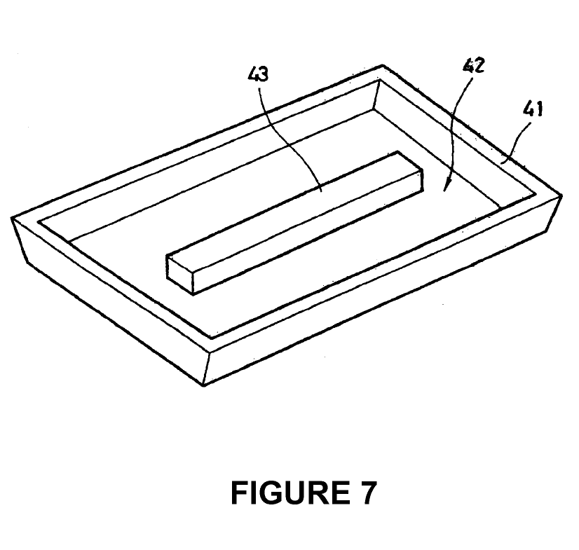

The second release sheet was removed from the copper foil laminated sample to expose the first pressure sensitive adhesive layer. As shown in FIG. 7, the copper foil laminated sample 43 was adhered to the bottom surface 42 of the stainless steel bat 41, and then, a roller with 2 kg was reciprocated from the side of the copper foil to fix.

Thereafter, a toluene solution of ethylene vinyl acetate (EVA) was poured into the stainless steel bat 41. The copper foil laminated sample 43 was fully embedded, and then dried, whereby the double-coated adhesive sheet covered with the copper foil on one side (copper foil laminated sample 43) was embedded (sealed) in EVA.

### (2) Fitting Adhesiveness by EVA

The EVA surface of the area covering the top side of the double-coated adhesive sheet was cut by slits to form a square of 5 mm×5 mm, and a pressure sensitive adhesive tape (cellophane tape) was stuck on the square. Then, the tape was removed at a stroke to examine whether or not the EVA was peeled. The peeling test was carried out 5 times, and the number of times where the EVA was not peeled was determined.
∘ Excellent: 5/5. EVA was not peeled.
   Acceptable: 4/5. EVA was peeled only once.
x Unacceptable: 3/5 to 0/5. EVA was peeled more than two times.

### (3) Presence or Absence of Bubbles of EVA on the Periphery of the Double-Coated Adhesive Sheet

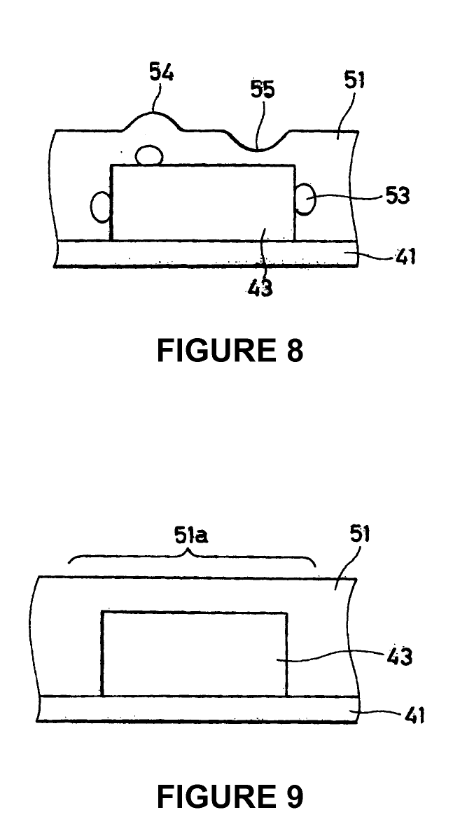

In the bat 41 as shown in FIG. 8 (a schematic cross-sectional view), the presence or absence of bubbles 53 on the surface of the copper foil laminated sample 43 embedded in EVA 51 was visually observed, and then an evaluation was made according to the following criteria. Further, on the surface of EVA, the presence of convex prominences 54 formed by the bubbles and concave dents 55 formed by bubble traces was also evaluated.
∘ Excellent: no bubble was observed in EVA, further no convex or concave trace of bubble was observed on the surface of EVA.
Δ Acceptable: no bubble was observed in EVA, but convex or concave traces of bubbles were only slightly observed on the surface of EVA.
x Unacceptable: multiple bubbles were observed in EVA, further multiple convex or concave traces of bubbles were observed on the surface of EVA.

### (4) Concavo-Convex Structure of EVA on the Periphery of the Double-Coated Adhesive Sheet

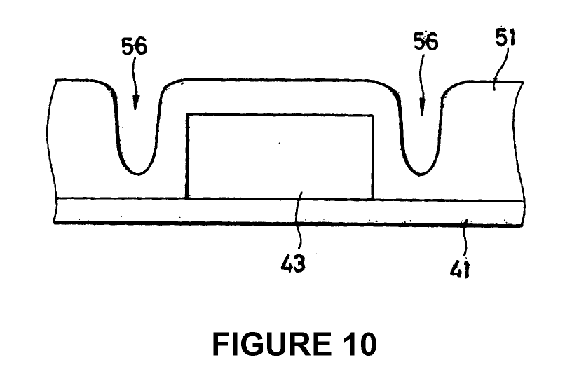

In the bat 41, the copper foil laminated sample 43 was observed as to whether or not the upper surface of the copper foil laminated sample 43 was flat as shown in FIG. 9 (a schematic cross-sectional view), and then evaluated according to the following criteria. Further, the copper foil laminated sample 43 was visually observed as to whether or not groove-like structures 56 as shown in FIG. 10 (a schematic cross-sectional view) were formed on the sides thereof, and then evaluated according to the following criteria.
∘ Excellent: as shown in FIG. 9, the surface of EVA was flat.
Δ Acceptable: EVA in proximity to the double-coated adhesive sheet was slightly dented.
x Unacceptable: as shown in FIG. 10, EVA in proximity to the double-coated adhesive sheet was scooped out greatly like the valley.

### 3. Resistance to Soldering Heat

The procedures described in Item “(1) Fabrication of adhesion sample” given in Item 1 “1. Adhesive strength to stainless steel plate and change in appearance” was repeated to obtain a polyimide laminated sample composed of “stainless steel plate/a first pressure sensitive adhesive layer/a PET film layer/a second pressure sensitive adhesive layer/a PI film layer/a third pressure sensitive adhesive layer/a PI film layer”. An electrothermal soldering iron having a tip of 0.4 mmR and heated to 260° C.±5° C. was pressed on the outermost polyimide layer of the polyimide laminated sample under the conditions of a pressing strength of 100 g (including a self weight of the soldering iron) for 10 seconds, and the state of the adhesive layers where the soldering iron was pressed was observed from the outermost polyimide layer.
∘ Excellent: No change was observed.
Δ Acceptable: Slight traces of bubbles existed in the adhesive layers, or slightly melt or softened traces were observed.
x Unacceptable: Multiple traces of bubbles were observed in the adhesive layers, or melt or softened traces were clearly observed.

### Comparative Examples 1-12

The procedure described in Example 1 was repeated, except that the acrylic polymers shown in Table 1 were used instead of the acrylic polymer used as main components in Example 1, to prepare pressure sensitive adhesive compositions. Thereafter, the procedure described in Example 2 was repeated to obtain double-coated adhesive sheets. Further, properties of the double-coated adhesive sheets were evaluated by the above procedures.

### Comparative Example 13

The procedure described in Example 1 was repeated, except that 30 parts by weight of polymerized rosin ester (manufactured by Arakawa Chemical Industries, Ltd. Pencell D125) were added as a tackifying resin with respect to 100 parts of the acrylic polymer, to prepare a pressure sensitive adhesive composition. Thereafter, the procedure described in Example 2 was repeated, to obtain a double-coated adhesive sheet. Further, properties of the double-coated adhesive sheet were evaluated by the above procedure.

### Comparative Example 14

The procedure described in Example 1 was repeated, except that 1.6 parts by weight of JER828 (difunctional epoxy compound; manufactured by Japan Epoxy Resins Co., Ltd.) were used instead of N,N,N′,N′-tetraglycidyl-m-xylylenediamine (tetrafunctional epoxy compound) used as a curing agent in Example 1, to prepare a pressure sensitive adhesive composition. Thereafter, the procedure described in Example 2 was repeated, to obtain a double-coated adhesive sheet. Further, properties of the double-coated adhesive sheet were evaluated by the above procedure.

### Comparative Example 15

The procedure described in Example 1 was repeated, except that 1.6 parts by weight of JER828 (difunctional epoxy compound; manufactured by Japan Epoxy Resins Co., Ltd.) were used instead of N,N,N′,N′-tetraglycidyl-m-xylylenediamine (tetrafunctional epoxy compound) used as a curing agent in Example 1, to prepare a pressure sensitive adhesive composition. Thereafter, the procedure described in Example 2 was repeated, to obtain a double-coated adhesive sheet. Further, properties of the double-coated adhesive sheet were evaluated by the above procedure.

### Comparative Example 16

The procedure described in Example 1 was repeated, except that 0.64 part by weight of YDCN700-7 (pentafunctional novolac-type epoxy compound; manufactured by Tohto Kasei Co., Ltd.) was used instead of N,N,N′,N′-tetraglycidyl-m-xylylenediamine (tetrafunctional epoxy compound) used as a curing agent in Example 1, to prepare a pressure sensitive adhesive composition. Thereafter, the procedure described in Example 2 was repeated, to obtain a double-coated adhesive sheet. Further, properties of the double-coated adhesive sheet were evaluated by the above procedure.

### Comparative Example 17

In ethyl acetate and toluene, 50% by weight of butyl acrylate, 40% by weight of ethyl acrylate and 10% by weight of 2-hydroxyethyl methacrylate were copolymerized to obtain an acrylic polymer solution having a weight-average molecular weight of 650 thousands and a glass transition temperature (theoretical value) of about −30° C. 1 part by weight of tridiisocyanate (TDI) was incorporated thereto as a curing agent with respect to 100 parts (solid content) by weight of the acrylic polymer solution to obtain an acrylic pressure sensitive adhesive composition. Thereafter, the procedure described in Example 2 was repeated wherein the acrylic pressure sensitive adhesive composition obtained was used, to obtain a double-coated adhesive sheet. Further, properties of the double-coated adhesive sheet were evaluated by the above procedure.

### Comparative Example 18

The procedure described in Example 1 was repeated, except that a silicone pressure sensitive adhesive containing 100 parts by weight of a silicone pressure sensitive adhesive (SD4570; manufactured by Dow Corning Toray Co., Ltd.; solid content=60%) and 0.9 part by weight of a platinum catalyst-based curing agent (SRX212) was used instead of the acrylic pressure sensitive adhesive prepared in Example 1, to prepare a pressure sensitive adhesive composition. Thereafter, the procedure described in Example 2 was repeated, to obtain a double-coated adhesive sheet. Further, properties of the double-coated adhesive sheet were evaluated by the above procedure.

### Comparative Example 19

The acrylic pressure sensitive adhesive composition prepared in Example 1 was used to fabricate a double-coated adhesive sheet according to the following procedure. Further, properties of the double-coated adhesive sheet were evaluated by the above procedure.

### (1) First Step

The acrylic pressure sensitive adhesive composition prepared in Example 1 was coated on one side of a first release sheet, and then dried to form an adhesive layer [corresponding to the third pressure sensitive adhesive layer] having a thickness of 50 μm. Thereafter, a polyimide (PI) film having a thickness of 125 μm was laid on the third pressure sensitive adhesive layer to obtain a two-layered laminate (on the first release sheet) comprising the PI film layer (thickness=125 μm)/the third pressure sensitive adhesive layer (thickness=50 μm)/the first release sheet.

### (2) Second Step

The acrylic pressure sensitive adhesive composition prepared in Example 1 was coated on one side of a second release sheet, and then dried to form an adhesive layer [corresponding to the first pressure sensitive adhesive layer] having a thickness of 50 μm. Thereafter, the polyimide film surface of the laminate obtained in the above first step (1) was laid on the first pressure sensitive adhesive layer to obtain a double-coated adhesive sheet of a five-layered laminate (between the first release sheet and the second release sheet) comprising the second release sheet/the first pressure sensitive adhesive layer (thickness=50 μm)/the PI film layer (thickness=125 μm)/the third pressure sensitive adhesive layer (thickness=50 μm)/the first release sheet.

### (3) Evaluation of Properties

The results of the evaluation of properties about the double-coated adhesive sheets obtained are shown in the following Tables 2 to 4. A polyimide (PI) has a moisture absorption higher than a polyethylene terephthalate (PET). Therefore, if the adhesion sample without a PET layer was allowed to stand under the conditions of a high temperature and a high humidity, bubbles were formed in the adhesive layers via the PI and the adhesive strength was also lowered. Furthermore, moisture was derived from a thick PI film layer, many bubbles were formed within the EVA when embedded with the EVA.

### Comparative Example 20

The acrylic pressure sensitive adhesive composition prepared in Example 1 was used to fabricate a double-coated adhesive sheet by the following procedure. Further, properties of the double-coated adhesive sheet were evaluated by the above procedure.

### (1) First Step

The acrylic pressure sensitive adhesive composition prepared in Example 1 was coated on one side of a first release sheet, and then dried to form an adhesive layer [corresponding to a third pressure sensitive adhesive layer] having a thickness of 50 μm. Thereafter, on the third pressure sensitive adhesive layer, a polyethylene terephthalate film having a thickness of 125 μm was laid to obtain a two-layered laminate (on the first release sheet) comprising the PET film layer (thickness=125 μm)/the third pressure sensitive adhesive layer (thickness=50 μm)/the first release sheet.

### (2) Second Step

The acrylic pressure sensitive adhesive composition prepared in Example 1 was coated on one side of a second release sheet, and then dried to form an adhesive layer [corresponding to a first pressure sensitive adhesive layer] having a thickness of 50 μm. Thereafter, the polyethylene terephthalate film surface of the two-layered laminate obtained in the above first step (1) was laid on the first pressure sensitive adhesive layer to obtain a double-coated adhesive sheet of a three-layered laminate structure (between the first release sheet and the second release sheet) composed of a five-layered laminate (between the first release sheet and the second release sheet) comprising the second release sheet/the first pressure sensitive adhesive layer (thickness=50 μm)/the PET film layer (thickness=125 μm)/the third pressure sensitive adhesive layer (thickness=50 μm)/the first release sheet.

### (3) Evaluation of Properties

The results of the evaluation of properties about the double-coated adhesive sheet obtained are shown in the following Tables 2 to 4. A polyethylene terephthalate (PET) shows a thermal shrinkage larger than a polyimide (PI). Therefore, when the adhesion sample without a PI layer was allowed to stand under the conditions of a high temperature, a remarkable shrinkage occurred and an adhesive strength was also reduced. Furthermore, when a resistance to a soldering heat was evaluated, a PET having a thickness of 125 μm was melted to form pores.

TABLE 1

| | Main Components | | | | | | | | | Tackifying |
|---|---|---|---|---|---|---|---|---|---|---|
| | BA | EA | AA | 2EHA | MA | 2HEMA | Tg(° C.) | Mw | Curing agent | resin |
| Example 1 | 70 | 20 | 10 | 0 | 0 | 0 | −30.3 | 650000 | TETRAD-X: 4-epoxy | No |
| Comparative Example 1 | 45 | 40 | 15 | 0 | 0 | 0 | −16.5 | 600000 | TETRAD-X: 4-epoxy | No |
| Comparative Example 2 | 85 | 0 | 15 | 0 | 0 | 0 | −28.5 | 800000 | TETRAD-X: 4-epoxy | No |
| Comparative Example 3 | 82 | 3 | 15 | 0 | 0 | 0 | −27.6 | 800000 | TETRAD-X: 4-epoxy | No |
| Comparative Example 4 | 50 | 43 | 7 | 0 | 0 | 0 | −28.1 | 600000 | TETRAD-X: 4-epoxy | No |
| Comparative Example 5 | 55 | 40 | 5 | 0 | 0 | 0 | −32.2 | 600000 | TETRAD-X: 4-epoxy | No |
| Comparative Example 6 | 70 | 5 | 25 | 0 | 0 | 0 | −11.3 | 700000 | TETRAD-X: 4-epoxy | No |
| Comparative Example 7 | 0 | 25 | 15 | 60 | 0 | 0 | −31.8 | 600000 | TETRAD-X: 4-epoxy | No |
| Comparative Example 8 | 70 | 0 | 10 | 0 | 20 | 0 | −24.3 | 700000 | TETRAD-X: 4-epoxy | No |
| Comparative Example 9 | 50 | 28 | 22 | 0 | 0 | 0 | −9.1 | 600000 | TETRAD-X: 4-epoxy | No |
| Comparative Example 10 | 80 | 13 | 7 | 0 | 0 | 0 | −37.1 | 750000 | TETRAD-X: 4-epoxy | No |
| Comparative Example 11 | 70 | 20 | 10 | 0 | 0 | 0 | −30.3 | 400000 | TETRAD-X: 4-epoxy | No |
| Comparative Example 12 | 70 | 20 | 10 | 0 | 0 | 0 | −30.3 | 1000000 | TETRAD-X: 4-epoxy | No |
| Comparative Example 13 | 70 | 20 | 10 | 0 | 0 | 0 | −30.3 | 650000 | TETRAD-X: 4-epoxy | Yes |
| Comparative Example 14 | 70 | 20 | 10 | 0 | 0 | 0 | −30.3 | 650000 | JER828: 2-epoxy | No |
| Comparative Example 15 | 70 | 20 | 10 | 0 | 0 | 0 | −30.3 | 650000 | JER828: double amount | No |
| Comparative Example 16 | 70 | 20 | 10 | 0 | 0 | 0 | −30.3 | 650000 | YDCN700-7: 5-epoxy | No |
| Comparative Example 17 | 50 | 40 | 0 | 0 | 0 | 10 | −29.3 | 650000 | TDI | No |

Abbreviations in Table 1:
4-epoxy = Tetrafunctional epoxy
2-epoxy = Difunctional epoxy
5-epoxy = Pentafunctional epoxy

TABLE 2

| | Adhesive strength and appearance | | | | | | Molding | | | |
|---|---|---|---|---|---|---|---|---|---|---|
| | Early stage | | 85° C.-85% × 1000H | | 150° C. × 1000H | | appropriateness | | | RSH |
| | N/inch | Appe. | N/inch | Appe. | N/inch | Appe. | FA | Bub. | Irr. | Appe. |
| Example 1 | 10 | ∘ | 20 | ∘ | 22 | ∘ | ∘ | ∘ | ∘ | ∘ |
| | | | | ND | | ND | E | E | E | E |
| Comparative Example 1 | 11 | ∘ | 18 | ∘ | 20 | Δ | ∘ | ∘ | ∘ | Δ |
| | | | | ND | | SPE | E | E | E | FB |
| Comparative Example 2 | 8 | ∘ | 17 | ∘ | 16 | x | ∘ | ∘ | ∘ | Δ |
| | | | | ND | | RO | E | E | E | SM, FB |
| Comparative Example 3 | 10 | ∘ | 18 | ∘ | 20 | ∘ | Δ | ∘ | ∘ | Δ |
| | | | | ND | | ND | 4/5 | E | E | SM, FB |
| Comparative Example 4 | 12 | ∘ | 18 | ∘ | 18 | Δ | ∘ | ∘ | ∘ | Δ |
| | | | | ND | | SPE | E | E | E | SM |
| Comparative Example 5 | 5 | ∘ | 12 | Δ | 16 | Δ | ∘ | ∘ | ∘ | Δ |
| | | | | SPE | | SRO | E | E | E | SM |
| Comparative Example 6 | 13 | ∘ | 22 | Δ | 24 | ∘ | Δ | ∘ | ∘ | x |
| | | | | Bub. | | ND | 4/5 | E | E | Bub. |

Abbreviations in Tables 2-4:
RSH = Resistance to Soldering heat
Appe. = Appearance
FA = Fitting Adhesiveness
Bub. = Bubbles
Irr. = Irregularity
ND = No defect
PE = Peeling at edge
SPE = Slightly peeling at edge
M = Melted
SM = Slightly melted
E = Excellent
FB = Fine Bubbles
BR = Barely repelled
RO = Running off
SRO = Slightly running off
MPS = Melted to pierce substrate
SB = Slight bubbles
OLB = One large bubble
LS = Large shrinkage
P = Peeling

TABLE 3

| | Adhesive strength and appearance | | | | | | Molding | | | |
|---|---|---|---|---|---|---|---|---|---|---|
| | Early stage | | 85° C.-85% × 1000H | | 150° C. × 1000H | | appropriateness | | | RSH |
| | N/inch | Appe. | N/inch | Appe. | N/inch | Appe. | FA | Bub. | Irr. | Appe. |
| Comparative Example 7 | 9 | ∘ | 13 | x | 14 | Δ | Δ | x | ∘ | x |
| | | | | PE | | SRO | 4/5 | Bub. | E | Bub. |
| Comparative Example 8 | 12 | ∘ | 16 | Δ | 18 | Δ | Δ | Δ | ∘ | Δ |
| | | | | SPE | | SPE | 4/5 | SB | E | SM, FB |
| Comparative Example 9 | 11 | ∘ | 21 | Δ | 20 | x | ∘ | ∘ | ∘ | Δ |
| | | | | SPE | | P | E | E | E | FB |
| Comparative Example 10 | 8 | ∘ | 17 | Δ | 14 | x | ∘ | ∘ | ∘ | Δ |
| | | | | RO | | RO | E | E | E | SM |
| Comparative Example 11 | 12 | ∘ | 22 | Δ | 22 | x | ∘ | Δ | ∘ | Δ |
| | | | | RO | | RO | E | FB | E | SM |
| Comparative Example 12 | 6 | ∘ | 10 | x | 12 | x | ∘ | ∘ | ∘ | ∘ |
| | | | | PE | | P | E | E | E | E |
| Comparative Example 13 | 13 | ∘ | 22 | x | 1 | x | Δ | Δ | Δ | Δ |
| | | | | RO | | P | 4/5 | OLB | BR | M |

Abbreviations in Tables 2-4:
RSH = Resistance to Soldering heat
Appe. = Appearance
FA = Fitting Adhesiveness
Bub. = Bubbles
Irr. = Irregularity
ND = No defect
PE = Peeling at edge
SPE = Slightly peeling at edge
M = Melted
SM = Slightly melted
E = Excellent
FB = Fine Bubbles
BR = Barely repelled
RO = Running off
SRO = Slightly running off
MPS = Melted to pierce substrate
SB = Slight bubbles
OLB = One large bubble
LS = Large shrinkage
P = Peeling

TABLE 4

| | Adhesive strength and appearance | | | | | | Molding | | | |
|---|---|---|---|---|---|---|---|---|---|---|
| | Early stage | | 85° C.-85% × 1000H | | 150° C. × 1000H | | appropriateness | | | RSH |
| | N/inch | Appe. | N/inch | Appe. | N/inch | Appe. | FA | Bub. | Irr. | Appe. |
| Comparative Example 14 | 12 | ∘ | 14 | Δ | 13 | x | ∘ | ∘ | ∘ | Δ |
| | | | | RO | | RO | E | E | E | M |
| Comparative Example 15 | 10 | ∘ | 16 | Δ | 14 | Δ | ∘ | ∘ | ∘ | ∘ |
| | | | | RO | | SPE | E | E | E | E |
| Comparative Example 16 | 7 | ∘ | 8 | Δ | 9 | x | ∘ | ∘ | ∘ | ∘ |
| | | | | SPE | | SPE | E | E | E | E |
| Comparative Example 17 | 12 | ∘ | 14 | x | 16 | x | x | Δ | ∘ | ∘ |
| | | | | RO | | RO | 3/5 | FB | E | E |
| Comparative Example 18 | 7 | ∘ | 8 | ∘ | 9 | ∘ | x | ∘ | x | ∘ |
| | | | | ND | | ND | 1/5 | E | | E |
| Comparative Example 19 | 9 | ∘ | 15 | Δ | 18 | ∘ | ∘ | x | ∘ | Δ |
| | | | | Bub. | | ND | E | Bub. | E | FB |
| Comparative Example 20 | 9 | ∘ | 19 | ∘ | 16 | x | ∘ | ∘ | ∘ | x |
| | | | | ND | | LS | E | E | E | MPS |

Abbreviations in Tables 2-4:
RSH = Resistance to Soldering heat
Appe. = Appearance
FA = Fitting Adhesiveness
Bub. = Bubbles
Irr. = Irregularity
ND = No defect
PE = Peeling at edge
SPE = Slightly peeling at edge
M = Melted
SM = Slightly melted
E = Excellent
FB = Fine Bubbles
BR = Barely repelled
RO = Running off
SRO = Slightly running off
MPS = Melted to pierce substrate
SB = Slight bubbles
OLB = One large bubble
LS = Large shrinkage
P = Peeling

### Reference Example

The procedure described in Example 1 of U.S. Pat. No. 6,121,542 was repeated, except that the double-coated adhesive sheet fabricated in Example 2 or a commercially available silicone pressure sensitive adhesive double-coated tape (DOUBLE-FACE LEW411A; manufactured by TOYO INK MFG CO., LTD.) were used, to prepare a solar cell module. Thereafter, an appearance was evaluated.

Specifically, metallic wires were obtained by the procedure described in “1. Preparation of collecting electrode” in Example 1 of U.S. Pat. No. 6,121,542, and then, a photovoltaic element was obtained by the procedure described in “2. Preparation of photovoltaic element”. Thereafter, the procedure described in “3. Preparation of photovoltaic device” in Example 1 of U.S. Pat. No. 6,121,542 was repeated except that the double-coated adhesive sheet fabricated in Example 2 or the commercially available silicone pressure sensitive adhesive double-coated tape (DOUBLE-FACE LEW411A; manufactured by TOYO INK MFG CO., LTD.) were used, to obtain a photovoltaic device.

The resulting photovoltaic device was allowed to stand for 12 hours under the conditions of 35° C. and relative humidity (RH) of 90%, the procedure described in “4. Preparation of solar cell module” in Example 1 of U.S. Pat. No. 6,121,542 was repeated to obtain a solar cell module. The resulting solar cell modules were evaluated in accordance with the criteria for evaluating appearance as described above. In the solar cell module wherein the commercially available silicone pressure-sensitive adhesive double-coated tape (DOUBLE-FACE LEW411A; manufactured by TOYO INK MFG CO., LTD.) was used, bubbles were formed very slightly. On the other hand, in the solar cell module wherein the double-coated adhesive sheet fabricated in Example 2 was used, no bubbles were observed.

Although the present invention has been described with reference to specific embodiments, various changes and modifications obvious to those skilled in the art are possible without departing from the scope of the appended claims.

1. An acrylic pressure sensitive adhesive composition comprising (A) an acrylic polymer having a carboxyl group and (B) a tetrafunctional epoxy compound, without a substantial amount of a tackifying resin, wherein the acrylic polymer (A) has been prepared by copolymerizing
(a) 50% to 80% by weight of butyl acrylate,
(b) 5% to 40% by weight of ethyl acrylate, and
(c) 7% to 22% by weight of at least one carboxyl group-containing compound selected from the group consisting of acrylic acid, methacrylic acid, itaconic acid, crotonic acid, monobutyl maleate and 0-carboxyethyl acrylate; and which has a weight-average molecular weight (Mw) of about 600000 to about 800000 and a glass transition temperature of −35° C. to −1° C.

2. The acrylic pressure sensitive adhesive composition according to claim 1, comprising 0.1 to 3.0 parts by weight of the tetrafunctional epoxy compound (B), with respect to 100 parts by weight of the carboxyl group-containing acrylic polymer (A).

3. The acrylic pressure sensitive adhesive composition according to claim 1, wherein the acrylic polymer (A) has been prepared by copolymerizing
(a) 65% to 75% by weight of butyl acrylate,
(b) 15% to 25% by weight of ethyl acrylate,
(c) 10% to 15% by weight of the carboxyl group-containing compound.

4. The acrylic pressure sensitive adhesive composition according to claim 1, wherein the carboxyl group-containing compound is acrylic acid.

5. A double-coated adhesive sheet laminated in the following order:
(1) a first pressure sensitive adhesive layer,
(2) a polyester film layer,
(3) a second pressure sensitive adhesive layer,
(4) a polyimide film layer, and
(5) a third pressure sensitive adhesive layer,
wherein each of the first pressure sensitive adhesive layer, the second pressure sensitive adhesive layer and the third pressure sensitive adhesive layer is a layer formed from an acrylic pressure sensitive adhesive composition comprising (A) an acrylic polymer having a carboxyl group and (B) a tetrafunctional epoxy compound, without a substantial amount of a tackifying resin; and
wherein the acrylic polymer (A) has been prepared by copolymerizing
(a) 50% to 80% by weight of butyl acrylate,
(b) 5% to 40% by weight of ethyl acrylate,
(c) 7% to 22% by weight of at least one carboxyl group-containing compound selected from the group consisting of acrylic acid, methacrylic acid, itaconic acid, crotonic acid, monobutyl maleate and β-carboxyethylacrylate; and which has a weight-average molecular weight (Mw) of about 600000 to about 800000 and a glass transition temperature of −35° C. to −10° C.

6. The double-coated adhesive sheet according to claim 5, having an entire thickness of not less than about 150 μm.

7. The double-coated adhesive sheet according to claim 5, wherein a ratio (T2/T1) of a total thickness (T2) of the polyester film layer and the polyimide film layer, to a total thickness (T1) of the first pressure sensitive adhesive layer, the second pressure sensitive adhesive layer and the third pressure sensitive adhesive layer, is about 0.3 to 1.5.

8. The double-coated adhesive sheet according to claim 5, wherein a thickness of the first pressure sensitive adhesive layer is about 10% to about 40%, with respect to the entire thickness of the double-coated adhesive sheet.

9. The double-coated adhesive sheet according to claim 5, wherein a thickness of the third pressure sensitive adhesive layer is about 10% to about 40%, with respect to the entire thickness of the double-coated adhesive sheet.

10. The double-coated adhesive sheet according to claim 5, wherein the adhesive strength at an early stage of the first pressure sensitive adhesive layer is 5 to 20 N/inch.

11. The double-coated adhesive sheet according to claim 5, wherein the adhesive strength of the first pressure sensitive adhesive layer is 10 to 30 N/inch after the double-coated adhesive sheet is allowed to stand for 1000 hours under the conditions of 85° C. and relative humidity (RH) of 85%.

12. A photovoltaic device comprising:
(1) a substrate;
(2) at least a pair of photovoltaic elements having an interval therebetween are arranged in parallel to each other on the substrate, wherein each of the photovoltaic elements is a laminate comprising a lower electrode layer which is in contact with the surface of the substrate, a semiconductor layer placed on the lower electrode layer, and a light receiving transparent electrode arranged on the semiconductor layer;
(3) the double-coated adhesive sheet according to claim 5, arranged on the surface of the substrate in the gap formed between the pair of the photovoltaic elements, under the conditions that the gap is fully filled with the double-coated adhesive sheet and each photovoltaic element is brought into close contact with the double-coated adhesive sheet, and the double-coated adhesive sheet has a thickness the same as that of each photovoltaic element, wherein the first pressure sensitive adhesive layer is adhered to the substrate, and the third pressure sensitive adhesive layer is in contact with the adjacent light receiving transparent electrode;
(4) one or more pairs of collecting electrodes mounted continuously from the surface of the light receiving transparent electrode to the surface of the double-coated adhesive sheet, and
(5) a buss bar electrically connecting with the collecting electrodes on the surface of the double-coated adhesive sheet, and arranged so that the collecting electrodes are sandwiched between the surface of the double-coated adhesive sheet and the buss bar.

13. A photovoltaic device comprising:
(1) an electrically conductive substrate which is made of an electrically conductive material as a whole, or has an electrically conductive layer on at least one surface thereof,
(2) at least a pair of semiconductor layers having an interval therebetween are arranged in parallel to each other on one electrically conductive surface of the electrically conductive substrate;
(3) a light receiving transparent electrode arranged on the surface of each semiconductor layer;
(4) the double-coated adhesive sheet according to claim 5, arranged on the surface of the electrically conductive substrate in the gap formed between the pair of laminates comprising the semiconductor layer and the light receiving transparent electrode, under the conditions that the gap is fully filled with the double-coated adhesive sheet and each laminate is brought into close contact with the double-coated adhesive sheet, and the double-coated adhesive sheet has a thickness the same as that of each laminate, wherein the first pressure sensitive adhesive layer is adhered to the substrate, and the third pressure sensitive adhesive layer is in contact with the adjacent light receiving transparent electrode;
(5) one or more pairs of collecting electrodes mounted continuously from the surface of the light receiving transparent electrode to the surface of the double-coated adhesive sheet, and
(6) a buss bar electrically connecting with the collecting electrodes on the surface of the double-coated adhesive sheet, and arranged so that the collecting electrodes are sandwiched between the surface of the double-coated adhesive sheet and the buss bar.

14. A photovoltaic device comprising:
(1) an electrically conductive substrate which is made of an electrically conductive material as a whole, or has an electrically conductive layer on at least one surface thereof,
(2) at least a pair of semiconductor layers having an interval therebetween are arranged in parallel to each other on one electrically conductive surface of the electrically conductive substrate;
(3) the double-coated adhesive sheet according to claim 5, arranged on the surface of the electrically conductive substrate in the gap formed between the pair of the semiconductor layers, under the conditions that the gap is fully filled with the double-coated adhesive sheet and each semiconductor layer is brought into close contact with the double-coated adhesive sheet, and the double-coated adhesive sheet has a thickness the same as that of each semiconductor layer, wherein the first pressure sensitive adhesive layer is adhered to the substrate, and the third pressure sensitive adhesive layer is in contact with the adjacent semiconductor layer;
(4) one or more pairs of collecting electrodes mounted continuously from the surface of the semiconductor layer to the surface of the double-coated adhesive sheet, and
(5) a buss bar electrically connecting with the collecting electrodes on the surface of the double-coated adhesive sheet, and arranged so that the collecting electrodes are sandwiched between the surface of the double-coated adhesive sheet and the buss bar.

15. A photovoltaic device photovoltaic device comprising:
(1) an electrically conductive substrate which is made of an electrically conductive material as a whole, or has an electrically conductive layer on at least one surface thereof,
(2) at least a pair of semiconductor layers having an interval therebetween are arranged in parallel to each other on one electrically conductive surface of the electrically conductive substrate;
(3) a light receiving transparent electrode disposed on the surface of each semiconductor layer;
(4) the double-coated adhesive sheet according to claim 5, arranged on the surface of the electrically conductive substrate in the gap formed between the pair of laminates comprising the semiconductor layer and the light receiving transparent electrode, under the conditions that the gap is fully filled with the double-coated adhesive sheet and each laminate is brought into close contact with the double-coated adhesive sheet, and the double-coated adhesive sheet has a thickness the same as that of each laminate, wherein the first pressure sensitive adhesive layer is adhered to the substrate, and the third pressure sensitive adhesive layer is in contact with the adjacent light receiving transparent electrode;
(5) one or more pairs of collecting electrodes mounted continuously from the surface of the light receiving transparent electrode to the surface of the double-coated adhesive sheet, and
(6) a buss bar electrically connecting with the collecting electrodes on the surface of the double-coated adhesive sheet, and arranged so that the collecting electrodes are sandwiched between the surface of the double-coated adhesive sheet and the buss bar.

16. A photovoltaic device comprising:
(1) an electrically conductive substrate which is made of an electrically conductive material as a whole, or has an electrically conductive layer on at least one surface thereof,
(2) at least a pair of semiconductor layers having an interval therebetween are arranged in parallel to each other on one electrically conductive surface of the electrically conductive substrate;
(3) the double-coated adhesive sheet according to claim 5, arranged on the surface of the electrically conductive substrate in the gap formed between the pair of the semiconductor layers, under the conditions that the gap is fully filled with the double-coated adhesive sheet and each semiconductor layer is brought into close contact with the double-coated adhesive sheet, and the double-coated adhesive sheet has a thickness the same as that of each semiconductor layer, wherein the first pressure sensitive adhesive layer is adhered to the substrate, and the third pressure sensitive adhesive layer is in contact with the adjacent semiconductor layer,
(4) one or more pairs of collecting electrodes mounted continuously from the surface of the semiconductor layer to the surface of the double-coated adhesive sheet, and
(5) a buss bar electrically connecting with the collecting electrodes on the surface of the double-coated adhesive sheet, and arranged so that the collecting electrodes are sandwiched between the surface of the double-coated adhesive sheet and the buss bar.
